(19) United States
(12) Patent Application Publication
(10) Pub. No.: US 2025/0383383 A1
(43) Pub. Date: Dec. 18, 2025

(54) METHOD AND SYSTEM FOR REMOTE CONTROL OF COMMUNICATING METERS

(71) Applicant: SAGEMCOM ENERGY & TELECOM SAS, BOIS-COLOMBES (FR)

(72) Inventors: Jérémie SERGI, BOIS-COLOMBES (FR); Pierre-Stéphane DIAZ, BOIS-COLOMBES (FR)

(21) Appl. No.: 19/208,574

(22) Filed: May 14, 2025

(30) Foreign Application Priority Data
Jun. 18, 2024 (FR) 2406457

(51) Int. Cl. G01R 22/06

(52) U.S. Cl. CPC G01R 22/063; G01R 22/068

(57) ABSTRACT

A set of smart meters is supplied by a power distribution network and in communication with a management and collection system for managing and collecting consumption data, the meters being configured to measure and manage power consumption. The method includes the steps, implemented by a gateway between the management and collection system and the set of meters, of receiving commands for one or more meters from the management and collection system, said commands being intended to be carried out by the meters in question; and sending the commands to the meters in question, where sending the commands comprises implementing a process for limiting a quantity of commands sent during a defined period of time.

### CROSS-REFERENCE TO RELATED APPLICATIONS

The present application claims priority to French Application No. 2406457 filed with the Intellectual Property Office of France on Jun. 18, 2024, which is incorporated herein by reference in its entirety for all purposes.

### TECHNICAL FIELD OF THE INVENTION

The present invention relates to systems for managing and collecting consumption data, such as AMM (advanced metering management) systems, mainly used in power (electricity, gas, water) distribution systems and networks. The invention relates more particularly to a method for the remote control of smart meters supplied by the power distribution network.

### PRIOR ART

The role of a system for managing and collecting consumption data, such as an AMM system, is to collect, measure, analyze and manage power (electricity, gas, water) consumption automatically and in real time. It uses smart meters, which measure power consumption at regular time intervals and manage power consumption. Smart meters are capable of transmitting power consumption data to a collection subsystem, usually called the HES (head-end system), of the AMM system via a communications network. The HES acts as a gateway between the AMM system and the meters. The consumption data received by the HES from the meters are then sent to a consumption data management system, usually called the MDMS (meter data management system), of the AMM system. The MDMS provides comprehensive, secure management of the consumption data. The AMM system also comprises a customer management system (CMS), which communicates with the MDMS and manages the interaction with customers.

Smart meters can receive remote commands from an entity in the AMM management system (for example from the CMS, MDMS or HES). These commands are intended to be carried out by the meters in question, and may comprise read commands, configuration commands, control commands, maintenance commands, alarm and notification commands, security commands, reporting commands, and so on. Some commands, known as “critical” commands, are liable to result in a power cut. Critical commands can comprise, in particular:
power cut orders; and
power limiting commands instructing the meters in question to reduce the maximum power available, which in the short term may lead to a power cut.

Disconnecting the power supply at a meter brings about a sudden drop in power consumption at a delivery point corresponding to a specific location where the power is supplied to an end user. If the power supply is disconnected (i.e. cut) at a large number of delivery points over a short period of time, typically of the order of a few minutes, via a large number of critical commands being sent to the meters managing these delivery points, this can bring about a sudden and significant imbalance between power generation and consumption. The reason for this imbalance is that power generation sources generally have a long response time, and the power distribution network does not have sufficient energy storage capacity to act as a buffer in these circumstances. This can lead to a blackout, i.e. a total or near-total failure of the power supply in a region, a city or even an entire country.

The mass sending of disconnect commands to smart meters can be caused by one or more human errors in the management or operation of the network, or by a malicious attack on one or more components of the AMM system.

It should be noted that a similar risk of imbalance also exists when a large number of delivery points are connected over a short period of time by sending a large number of remote connect commands to the meters in question.

The present invention aims to improve the situation, in particular limit the risk of an imbalance between power generation and consumption which, in certain circumstances, can lead to a blackout in the power distribution network.

### DESCRIPTION OF THE INVENTION

The present invention relates to a method for the remote control of a set of smart meters supplied by a power distribution network and in communication with a management and collection system for managing and collecting consumption data, said meters being configured to measure and manage power consumption, said method comprising the steps, implemented by a gateway between the management and collection system and the set of meters, of:
receiving commands for one or more meters from the management and collection system, said commands being intended to be carried out by the meters in question; and
sending the commands to the meters in question;

wherein sending the commands comprises implementing a process for limiting a quantity of commands sent during a defined period of time.

The management and collection system is, for example, an AMM (advanced metering management) system. The security between the subsystems or components of the AMM (HES, MDMS, CMS) can be compromised, leading to a significant risk of disruption or even blackout in the power distribution network. Specifically, in an AMM system, communications between the components (HES, MDMS, CMS) are generally protected in terms of integrity and confidentiality, for example by the TLS protocol. However, the AMM system comprises a large number of interfaces to be secured between its subsystems, as well as within each subsystem, and software components that may be vulnerable to security risks (or common vulnerability exposure (CVE)). Due to the complex and sensitive structure of the AMM system in terms of security, the risk of compromise cannot be neglected.

The AMM system allows critical commands to be sent remotely from several levels of the system (CMS, MDMS, HES). Human error can trigger the mass sending of a critical command to a very large number of meters.

The AMM system can use a data protection mechanism, such as “data protection” from the DLMS (Device Language Message Specification) standard, which is a standard communication protocol used mainly in the field of power management. This protection mechanism makes it possible to secure a command sent to the meter using a key dedicated to the authentication of critical exchanges. However, this mechanism does not prevent a malicious user from sending a large number of authenticated commands.

The present invention adds a protection mechanism by implementing a limiting process that limits a quantity of commands sent per defined period of time. This protection mechanism can be implemented in the management and collection system, more specifically in a subsystem acting as a gateway between the management and collection system and the set of meters. It can be implemented just before the gateway sends the command to the one or more targeted meters.

This limiting process adds extra protection mainly against two threats:
human error, triggered for example by a user of the management and collection system legitimately entitled to initiate the execution of commands;
compromise of one or more components of the management and collection system liable to send remote commands to the meters via the gateway.

The invention thus adds protection against such threats in the event that the protective barriers of the prior art have been breached.

Advantageously,
step sending the commands comprises a step of classifying each command as critical or non-critical on the basis of a predetermined list of one or more critical commands; and
the limiting process is carried out only for the critical commands.

In one embodiment, the limiting process comprises the steps of
monitoring a quantity of critical commands sent during said defined period of time with respect to a predetermined alarm threshold; and
after the alarm threshold has been reached, canceling the sending of any critical commands until said period of time has elapsed.

For example, different alarm thresholds can be applied to different types of critical commands.

In one embodiment, the method comprises, for any critical command for which the sending has been canceled, a step of notifying of the failure to send said critical command to at least one entity of the management and collection system.

Advantageously, the limiting process can be carried out iteratively over different defined periods of time, the quantity of critical commands sent being reset at the start of each new period of time.

For example, the limiting process is carried out iteratively:
in each period of time of a continuous series of consecutive periods of time;
in each period of time of a series of periods of time in which each new period of time is started, after the preceding period of time has elapsed, on sending a new critical command; or
over a sliding period of time.

In one particular embodiment, said period of time and the alarm threshold can be predetermined by machine learning on the basis of data on the use of critical commands by the management and collection system for managing and collecting consumption data.

In one embodiment, the limiting process can comprise the steps of:
detecting whether the quantity of commands to be sent reaches a warning threshold, lower than the alarm threshold, during the defined period of time;
in the event of positive detection, transmitting a warning message to at least one entity in the management and collection system, and continuing to send the one or more critical commands during said period of time.

In one embodiment, the limiting process can be carried out by a gateway communication module, responsible for generating and sending communication frames containing the commands to the meters in question via a communication infrastructure.

Advantageously, the function of limiting the commands, for example critical commands, is implemented in the communication module of the gateway, the role of which is to generate and send communication frames to the meters, these frames containing, for example, commands. By virtue thereof, the limiting process is carried out as close as possible to the time when the command is sent to the one or more meters via the communication network or infrastructure.

A second aspect of the invention also relates to a gateway between a set of smart meters supplied by a power distribution network and a management and collection system for managing and collecting consumption data, said meters being configured to measure and manage power consumption, said gateway comprising means for implementing the steps of the method defined above.

A third aspect of the invention relates to a management and collection system for managing and collecting consumption data, comprising the gateway defined above.

In one embodiment, the management and collection system further comprises
a data management system arranged to analyze the consumption data;
a customer management system arranged to manage the interaction with customer users,

wherein the commands for the meters are provided by at least one of the components comprising the data management system, the customer management system and the gateway.

A fourth aspect of the invention relates to a computer program comprising instructions which cause the gateway defined above to carry out the steps of the method defined above.

A fifth aspect of the invention relates to a non-volatile computer-readable storage medium on which the computer program according to the claim is recorded.

### DESCRIPTION OF THE FIGURES

Further features and advantages of the present invention will become more clearly apparent from the following detailed description of one embodiment of the invention, given by way of non-limiting example and illustrated by the accompanying drawings, in which:

FIG. 1 schematically shows an infrastructure for collecting and managing consumption data measured by smart meters, according to one particular embodiment;

FIG. 2 shows a block diagram of a collection system of the infrastructure shown in FIG. 1, according to one particular embodiment;

FIG. 3 shows a block diagram of a communication component of the collection system shown in FIG. 2, according to one particular embodiment;

FIG. 4 shows a flowchart of steps in a method for the remote control of meters, according to one particular embodiment.

### DETAILED DESCRIPTION OF ONE OR MORE EMBODIMENTS

The following detailed description describes various features and functions of the systems and methods disclosed with reference to the accompanying figures. In the figures, similar symbols identify similar components, unless stated otherwise. The illustrative embodiments of the system, device and method described herein are not limiting. A person skilled in the art will readily appreciate that certain aspects of the systems, devices and methods described herein may be arranged and combined in a wide variety of different configurations, all of which are considered here.

The present invention relates to a method and a system for the remote control of smart meters supplied by a power distribution network. The smart meters are arranged to measure and manage power consumption at a delivery point (PDL) and are in communication with a management and collection system for managing and collecting consumption data. The present invention improves the stability of the power (electricity, gas, or water) distribution network by implementing a process for limiting the number of remote commands sent by the management and collection system to the meters per defined period of time. This limiting process reduces the risk of imbalance between power generation and consumption, and therefore improves the stability of the power distribution network. It is carried out by a gateway responsible for interaction between the management and collection system and the meters via a communication network. The gateway is responsible for sending commands to the meters via the communication network, for example by inserting these commands into communication frames. Just before sending each new command, a communication module of the gateway, communicating with the meters, carries out the limiting process to detect whether the quantity of commands sent over the defined period of time has reached an alarm threshold. If the alarm threshold has already been reached within the defined period of time, the new command is not sent. Advantageously, this function of limiting the number of commands can be used only for critical commands liable to cause an imbalance in the power distribution network.

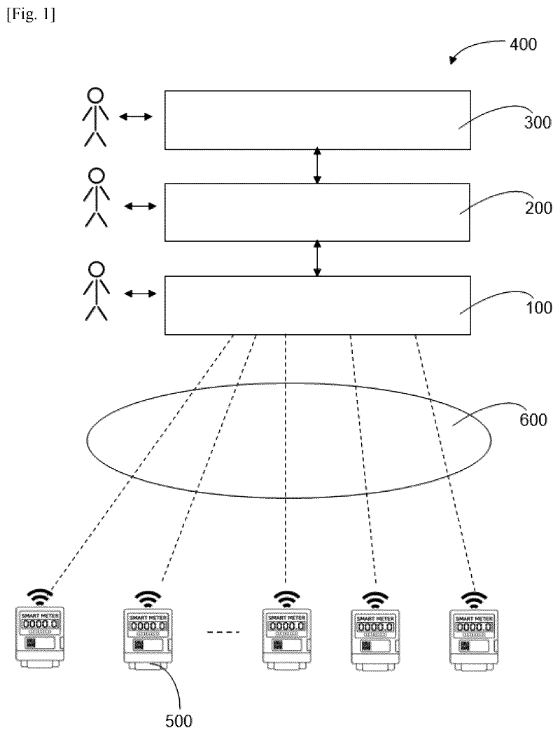

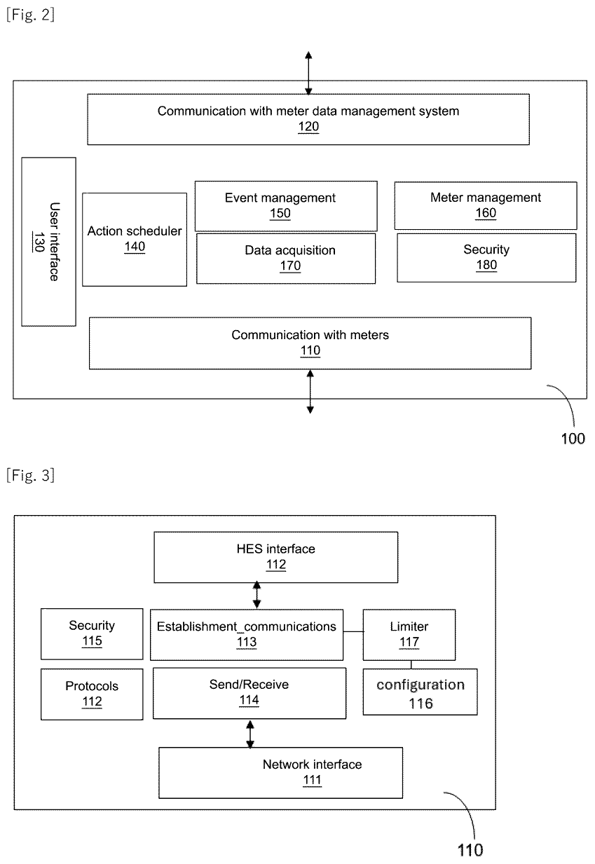

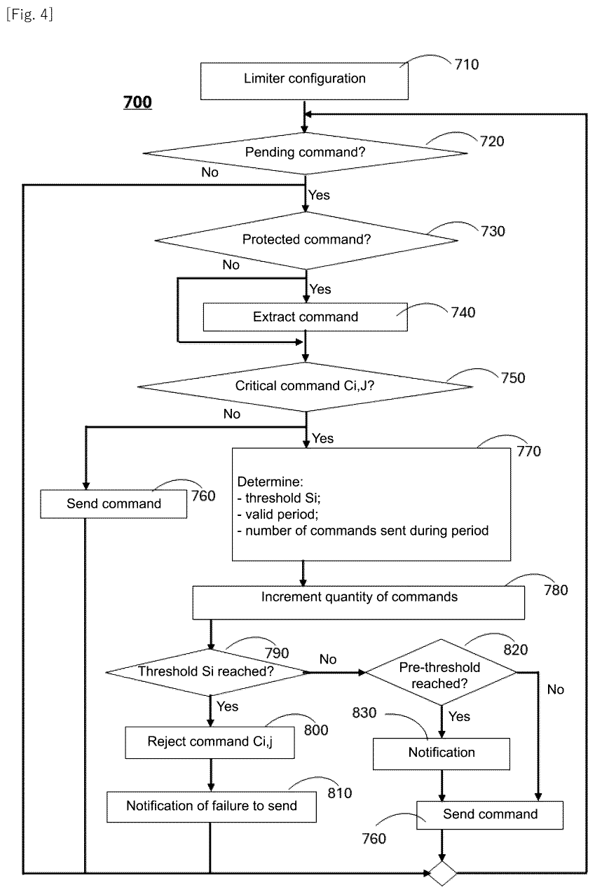

FIG. 1 schematically shows a management and collection system 400 for managing and collecting consumption data and a set of smart meters 500.

The smart meters 500 are supplied with power (electricity, gas or water) by a power distribution network (not shown) and allow automatic measurement of power consumption data remotely, without on-site human intervention. They are connected to the management and collection system 400 via a communication network or infrastructure 600, and can interact with the system 400.

The communication infrastructure 600 can comprise one or more networks, such as fixed and mobile telecommunication networks, RF mesh networks, PLC (power line communication), and so on. This infrastructure is external to the management and collection system 400.

The management and collection system 400, such as an AMM (advanced metering management) system, is a central system with the functions of collecting, measuring, analyzing and managing power (electricity, gas, water) consumption. In a known manner, the AMM system can comprise the following different components:
a head-end system (HES) 100;
a meter data management system (MDMS) 200; and
a customer management system (CMS) 300.

The role of the meter data management system (MDMS) 200 is to collect, store and analyze the data, in particular the consumption data, from the smart meters 500, facilitating the management of the consumption data and the use thereof for billing, usage analysis and network management.

The role of the customer management system (CMS) 300 is to manage customer information, including accounts, billing, payments and customer services. The CMS uses the data provided by the MDMS to generate bills and manage interactions with customers.

The head-end system (HES) 100 is a gateway between the management and collection system 400 and the meters 500. In particular, it is responsible for managing communication and interaction between the smart meters 500 and the system 400. The data collected by the meters 500 is transmitted to the meter data management system (MDMS) 200 via the head-end system (HES) 100. The management and collection system 400 can also transmit commands (e.g. read commands, configuration commands, control commands, e.g. to activate or deactivate the power supply, maintenance commands, etc.) and other data (e.g. software update data) from the management and collection system 400 to the meters 500. These commands and/or data from the management and collection system 400 are transmitted to the meters 500 via the head-end system (HES) 100. This acts as a gateway between the meters 500 and the central data collection and management system 400.

In one embodiment, the components of the head-end system (HES) 100 can include:
a communication module 110, communicating with the meters 500, responsible for communication with the meters 500 through the communication infrastructure 600;
a communication module 120 communicating with the meter data management system through one or more communication links;
a user interface module 130;
an action scheduler 140;
a meter management module 160;
a data acquisition module 170;
a security module 180.

The role of the action scheduler 140 is to orchestrate and manage the various tasks and commands to be carried out on the smart meters 500. For example, it can plan and prioritize operations on the meters (readings, updates, etc.), automatically trigger commands according to predefined schedules or events, and monitor task progress.

The role of the meter management module 160 is to manage all of the meters 500. For example, it can add and register new meters 500, and configure basic parameters and communication parameters on these new meters 500.

The data acquisition module 170 is responsible for collecting data from the meters 500. It can, for example, take regular or on-demand readings of power consumption data from the meters 500, and allow on-demand data collection for specific needs.

The security module 180 is responsible for managing the cryptographic keys used to secure communications and data transmitted between the head-end system 100 and the meters 500.

The communication module 110 is responsible for managing the interaction between the head-end system (HES) 100 and the meters 500. It comprises hardware and/or software components that can include:
network interface means 111 allowing the head-end system (HES) 100 to be connected to the communication infrastructure 600;
a communication protocol adapter 112 allowing various protocols or combinations of protocols (e.g. DLMS/TCP/IP, DLMS/UDP/IP, LwM2M/COAP/UDP/IP, LwM2M/COAP/TC″/IP, etc.) to be used to communicate with different types of meter 500;
a handshake block 113 for initializing and managing communication sessions between the head-end system 100 and the meters 500;
a data sending and/or receiving block 114 responsible for sending and receiving data (consumption data, software updates, commands, etc.) to or from the meters 500;
a security block 115 responsible for authenticating the meters 500 and encrypting/decrypting data exchanged with the meters 500.

In one embodiment, the sending and receiving block 114 is responsible for:
generating and sending communication frames to the meters 500 through the communication infrastructure 600;
receiving and processing communication frames from the meters 500 through the communication infrastructure 600.

According to the present invention, the communication module 110 further comprises a limiter 117, the role of which is to limit the quantity of commands transmitted per defined period of time to the meters 500. The limiter 117 can be connected to the sending and receiving block 114 or integrated into the sending and receiving block 114. In addition, it can be connected to a configuration block 116 that allows limiting parameters to be configured. The functions and operation of the limiter 117 and of the configuration block 116 will be described in more detail in the following description of a method for the remote control of meters 500, according to one particular embodiment.

A method 700 for the remote control of meters 500 will now be described according to one particular embodiment. The method 700 can be carried out by the communication module 110.

For the sake of clarity, only those steps of the control method 700 necessary for understanding the invention will be described herein. It should be noted that the control method 700 may comprise other steps which are not explicitly described herein but which may be incorporated into the implementation of the invention.

The head-end system HES 100 can send commands to the meters 500. These commands can originate from an entity of the management and collection system 400, for example from the meter data management system MDMS 200, from the customer management system CMS 300 or from the head-end system HES 100 itself. They can comprise different types of commands:
read commands to retrieve power consumption data over a defined period;
configuration commands to adjust parameters of the meter (e.g. configuration of measurement parameters, firmware updates, activation of specific functions, etc.);
control commands, e.g. to activate or deactivate the power supply, set the maximum power available to a consumer;
maintenance commands, for example to run tests to check the operating status of the meter;
etc.

Certain commands, such as control commands to deactivate the power supply and control commands to set the maximum power available, can have a significant impact on power consumption at the point of delivery. Such commands are considered critical. The present method 700 limits the quantity of critical commands sent to the meters 500 per defined period of time. Alternatively, the control method 700 could be applied to all commands for the meters 500.

The method comprises a step 710 of configuring the limiter 117, implemented by the configuration block 116. Step 710 can comprise configuring parameters for limiting the quantity of commands transmitted to the meters 500 per defined period of time. These limiting parameters can comprise all or some of:
parameters specifying the defined period of time which can include a duration and optionally a type of period of time;
a list of critical commands Ci, where i=1, 2, . . . , containing one or more critical commands and, for each critical command Ci, a specific alarm threshold Si.

Multiple types of period of time can be used by the limiter 117:
period of time of a continuous series of consecutive periods of time;
sliding period of time, which is defined by its duration and a current instant in time (end of the sliding period) and moves continuously forward as time passes;
period of time of a series of periods of time in which, after a preceding period of time has elapsed, a new period of time is only started when a new critical command is sent.

By way of illustrative and non-limiting examples, the list of critical commands can include a control command to deactivate power consumption (for example, a command to open a power supply switch) and a control command to reduce the maximum power available to a consumer.

The various critical commands Ci of the list can be associated with different alarm thresholds Si over the defined period of time. By way of purely illustrative and non-limiting examples, the thresholds can comprise a threshold of 1000 critical switch opening commands (i.e. 1000 power interruption commands) per hour and a threshold of ten security key renewal instructions per minute. In one variant, an identical alarm threshold could be configured for different critical commands. In another variant, a specific period of time could be defined for each critical command.

Optionally, the configuration parameters can comprise a warning threshold, lower than the alarm threshold. This warning threshold can be defined as a percentage of the alarm threshold, for example between 70% and 90% of the alarm threshold. It makes it possible to detect when the number of critical commands Ci per defined period of time is approaching the alarm threshold Si.

The configuration of the limiter 117 can be implemented by the configuration block 116. It can be carried out by a user via the user interface 130 of the head-end system HES 100. Alternatively, all or some of the configuration parameters could be configured upstream, for example by a manufacturer of the head-end system HES 100.

The configuration of limiter 117 is highly sensitive, and access thereto can be restricted to a dedicated user profile predefined in the HES system 100. Assigning the profile to a user can be managed according to the security rules of the system 400. The permissions associated with this profile can be checked by the HES system 100 whenever an attempt is made to modify the configuration of the limiter 117.

The configuration parameters can be stored in a memory in the head-end system 100. Advantageously, they can be stored in a secure memory or database of the head-end system 100, for example a memory or database managed by the security module 180.

Optionally, when starting up the communication module 110 and/or the gateway 100, the remote control method comprises a step of loading the configuration parameters of the limiter 117 from the secure memory or database of the head-end system HES 100 into a memory of the communication module 110, for example a volatile memory. The loading step can be followed by a test step of checking whether the configuration of the limiter 117 has taken place correctly, for example by checking whether limiting parameters have indeed been loaded into limiter 116 and optionally whether these parameters contain a non-empty list of critical commands.

If the test is negative (the configuration of the limiter 116 has not taken place correctly), the method 700 can comprise an alarm notification step. For example, an alarm message can be transmitted to an entity of the management and collection system 400 and/or to a user via a user interface such as that 130 of the head-end system HES 100. Alternatively, if the test is negative, the method 700 could be followed by a step of rejecting any command, whether critical or non-critical. This rejection step could be implemented by the limiter 117.

If the test is positive (i.e. the limiter 116 has been configured correctly), the method 700 can move on to a step 720 of checking commands pending transmission.

It should be noted that, in one variant, the test is also positive if the configuration of the limiter 117 comprises an empty list of critical commands. This allows the deployment of an HES 100 controlling only meters 500 not supporting commands considered critical.

The head-end system HES 100 manages and schedules the sending of commands to the meters 500, for example by means of the action scheduler 140. The commands to be transmitted, or pending transmission, are delivered to the communication module 110, which is responsible for sending them to the meters in question via the communication infrastructure 600. These commands pending transmission can be temporarily stored in a buffer of the head-end system HES 100.

In step 720, the communication module 110 checks whether one or more commands for meters 500 are pending transmission. If so, the communication module 110 obtains one of the commands pending transmission, for example by reading the buffer memory. It can, for example, obtain the highest-priority pending command. If not, the method moves on to an end step, waiting for commands to be transmitted.

If the command pending transmission is encrypted (730: yes), the method 700 can comprise a decryption step 740 of decrypting this command.

After decryption, or directly after obtaining the pending command if it is not encrypted, the method 700 comprises a step 750 of classifying the command as critical or non-critical. This classification can be carried out by comparing the command pending transmission Ci,j with the configured list of critical commands Ci of the limiter 117.

If the command pending transmission does not correspond to one of the critical commands Ci of the configured list of critical commands in the limiter 117, the method 700 moves directly on to a step 760 of sending the command to the meter in question 500, via the communication infrastructure 600.

In sending step 760, the communication module 110 can establish a communication session with the meter 500 in question, generate a communication frame containing the command to be transmitted, and transmit the communication frame containing the command. Optionally, the command and/or all or part of the communication frame can be encrypted.

In one embodiment, the limiting process is not applied to non-critical commands. Any number of these non-critical commands can be sent per defined period of time.

In the embodiment described herein, the limiting process is implemented for each type of critical command of the preconfigured list of critical commands Ci, over a series of defined periods of time. This series of periods can comprise a new period started, after the preceding period has elapsed, when a new critical command is sent.

Alternatively, this series of periods of time can be a continuous series of consecutive periods. In another variant, the period of time can be a sliding window.

For each type of critical command of the preconfigured list of critical commands, the limiter 117 counts the number of critical commands sent by the communication module 110 during each defined period of time. In other words, each period of time is associated with a count of critical commands sent.

If the command pending transmission Ci,j corresponds to one of the critical commands in the configured list of critical commands, the method 700 moves on to step 770 of determining, for this critical command:
an associated alarm threshold,
whether there is a valid (not elapsed), current, associated period of time; and
if applicable, a quantity of critical commands already sent during this valid period of time.

If it is determined in step 770 that there is no valid current period (the preceding period having already elapsed), a new period of time is started and limiter 117 resets and restarts a critical command count for this new period of time. Advantageously, the limiter 117 can add the present command Ci,j currently being sent to the count, in a step 780.

If it is determined in step 770 that a period of time is current and has not yet elapsed (valid period), the critical command count associated with this period of time is incremented (for example, by +1) in step 780 to take account of the critical command Ci,j currently being sent.

In other embodiments, such as a continuous series of consecutive periods of time or a sliding period of time, steps 770 and 780 will be adapted accordingly to take account of the specifics of these embodiments. For example, for a continuous series of consecutive periods of time, the limiter 117 can automatically trigger the next period and reset the count of the number of critical commands, once the preceding period has elapsed, without interruption, in steps 770 and 780. For a sliding period of time, step 770 can dynamically determine the start and end of the period of time according to predefined conditions, for example by setting the end of the period of time to the current time, or to a scheduled time for sending the pending command.

In a step 790, the method 700 comprises a step 790 of checking the alarm threshold Si. In this step 790, the limiter 117 checks whether the count of critical commands of type Ci for the current period has reached the corresponding alarm threshold Si, here after incrementing with the critical command currently being sent Ci,j.

In the event of a positive check in step 790 (i.e. if the critical command count has reached the alarm threshold Si over the current defined period of time, here after incrementing with the command Ci,j), the method 700 moves on to a step 800 of rejecting the critical command Ci,j. This critical command Ci,j is not sent. Thus, as soon as the critical command count reaches the alarm threshold Si, the sending of any critical command is rejected and canceled until the current defined period has elapsed.

The limiting process thus makes it possible to monitor a quantity of critical commands Ci sent during the defined period of time in relation to the alarm threshold Si, and, once the alarm threshold Si has been reached, to cancel the sending of any new critical commands Ci until this period has elapsed.

The rejection step 800 can be followed by a step 810 of notifying at least one entity of the management and collection system 400 of the failure to send the critical command Ci,j. For example, a notification message can be transmitted to the source entity that sent the critical command Ci,j and/or to a user of the head-end system HES 100 via the user interface 130.

In the event of a negative check in step 790 (i.e. if the critical command count has not reached the alarm threshold Si over the current period of time, here after incrementing with the command Ci,j), the method 700 moves on to a step 820 of checking the warning threshold, or pre-threshold before the alarm threshold Si. In this step 820, the limiter 117 checks whether the count of critical commands of type Ci for the current period has reached the corresponding warning threshold, which is, for example, equal to a certain percentage strictly lower than 100% of the alarm threshold Si.

In the event of a positive check in step 820 (i.e. if the critical command count has reached the warning threshold over the current period of time), the method 700 moves on to a step 830 of generating a warning message indicating that the quantity of critical commands Ci sent per defined period of time is approaching an alarm threshold. This warning message can be sent by the limiter 117 to one or more entities of the management and collection system 400, for example to the entity sending the critical command Ci,j and/or to a user of the head-end system HES 100 via the user interface 130. The method 700 then moves on to step 760 of sending the critical command Ci,j.

In the event of a negative check in step 820 (i.e. if the critical command count has not reached the warning threshold over the current period of time), the method 700 moves directly on to step 760 of sending the critical command Ci,j.

Step 760 of sending the critical command Ci,j is analogous to step 760 of sending the non-critical command described above. More precisely, the communication module 110 of the gateway 100 can establish a communication session with the meter 500 in question, generate a communication frame containing the critical command to be transmitted Ci,j, and transmit the communication frame containing the command Ci,j.

After the command has been rejected (800) or sent (760), some or all of steps 720 to 830 of the remote control method 700 described above are carried out iteratively. This iterative method can be interrupted if the communication module 110 and/or the gateway or head-end system (HES) 100 is shut down.

The steps of the limiting process, including steps 750, 770, 780, 790, 800, 810, 820, 830, can be carried out by the limiter 117.

In one embodiment, the one or more thresholds Si and the one or more parameters of the period of time (duration and/or type of period) used by the limiting process can be at least partially determined adaptively according to critical command usage by the system 400. For example, the one or more thresholds Si associated with the critical commands and, for each threshold, the associated period of time can be determined automatically by a machine learning module that makes it possible to configure the critical command thresholds Si and the associated one or more periods of time on the basis of data on the usage of critical commands by the system 400.

### INDUSTRIAL APPLICABILITY

A method and a system according to the present invention, and the production of the system, are industrially applicable.

It will be understood that various modifications and/or improvements obvious to a person skilled in the art may be made to the various embodiments of the invention disclosed in the present description without departing from the scope of the invention.

1. A method for the remote control of a set of smart meters supplied by a power distribution network and in communication with a management and collection system for managing and collecting consumption data, said meters being configured to measure and manage power consumption, said method comprising the steps, implemented by a gateway between the management and collection system and the set of meters, of:
receiving commands for one or more meters from the management and collection system, said commands being intended to be carried out by the meters in question; and
sending the commands to the meters in question;
wherein sending the commands comprises implementing a process for limiting a quantity of commands sent during a defined period of time;
detecting whether the quantity of commands to be sent reaches a warning threshold, lower than the alarm threshold, during the defined period of time;
in the event of positive detection, transmitting a warning message to at least one entity in the management and collection system, and continuing to send the one or more critical commands during said period of time.

2. The method as claimed in claim 1, wherein:
sending the commands comprises a step of classifying each command as critical or non-critical on the basis of a predetermined list of one or more critical commands; and
the limiting process is carried out only for the critical commands.

3. The method as claimed in claim 2, wherein the limiting process comprises the steps of
monitoring a quantity of critical commands sent during said defined period of time with respect to a predetermined alarm threshold; and
after the alarm threshold has been reached, canceling the sending of any critical commands until said period of time has elapsed.

4. The method as claimed in claim 3, wherein different alarm thresholds are applied to different types of critical commands.

5. The method as claimed in claim 3, comprising, for any critical command for which the sending has been canceled, a step of notifying of the failure to send said critical command to at least one entity of the management and collection system.

6. The method as claimed in claim 3, wherein the limiting process is carried out iteratively over different defined periods of time, the quantity of critical commands sent being reset at the start of each new period of time.

7. The method as claimed in claim 6, wherein the limiting process is carried out iteratively:
in each period of time of a continuous series of consecutive periods of time;
in each period of time of a series of periods of time in which each new period of time is started, after the preceding period of time has elapsed, on sending a new critical command; or
over a sliding period of time.

8. The method as claimed in claim 3, wherein said period of time and the alarm threshold are predetermined by machine learning on the basis of data on the use of critical commands by the management and collection system for managing and collecting consumption data.

9. The method as claimed in claim 1, wherein the limiting process is carried out by a gateway communication module, responsible for generating and sending communication frames containing the commands to the meters in question via a communication infrastructure.

10. A gateway between a set of smart meters supplied by a power distribution network and a management and collection system for managing and collecting consumption data, said meters being configured to measure and manage power consumption, said gateway comprising means for implementing the steps of the method as claimed in claim 1.

11. A management and collection system for managing and collecting consumption data, comprising the gateway of claim 10.

12. The management and collection system according to claim 10, further comprising
a data management system arranged to analyze the consumption data;
a customer management system arranged to manage the interaction with customer users,
wherein the commands for the meters are provided by at least one of the components comprising the data management system, the customer management system and the gateway.

13. A non-volatile computer-readable storage medium on which a computer program for carrying out a method according to claim 1 is recorded.
